(19) United States
(12) Patent Application Publication
(10) Pub. No.: US 2008/0257398 A1
(43) Pub. Date: Oct. 23, 2008

(54) Floating Solar Platform

(75) Inventors: Nikolaus Johannes Laing, Remseck (DE); Inge Laing, La Jolla, CA (US); Andreas Hesse, Olpe (DE)

Correspondence Address: FOLEY & LARDNER LLP, P.O. BOX 80278, SAN DIEGO, CA, 92138-0278, US

(73) Assignee: Pyron, INC.

(21) Appl. No.: 11/662,393

(22) PCT Filed: Sep. 7, 2005
(86) PCT No.: PCT/EP05/09593

§ 371 Date: Jun. 12, 2008

Related U.S. Application Data
(60) Provisional application No. 60/328,767, filed on Oct. 11, 2001.
(60) Provisional application No. 60/346,202, filed on Oct. 19, 2001.
(60) Provisional application No. 60/343,663, filed on Oct. 26, 2001.
(60) Provisional application No. 60/368,567, filed on Mar. 29, 2002.
(60) Provisional application No. 60/409,873, filed on Sep. 10, 2002.
(60) Provisional application No. 60/389,111, filed on Jun. 13, 2002.
(60) Provisional application No. 60/389,111, filed on Jun. 13, 2002.
(60) Provisional application No. 60/368,516, filed on Mar. 29, 2002.

(30) Foreign Application Priority Data
Sep. 8, 2004 (US) 10935396

(51) Int. Cl. H01L 31/042

(52) U.S. Cl. 136/246

(57) ABSTRACT

The invention describes large solar power plants, which consist of groups of rotating platforms. Three of said platforms comprising a triad having an interstitial pillar, said pillar has means to transmit torque to rotate the platforms and means to maintain the position of the platforms.

Photovoltaic power stations which contain a number of concentrators which are combined in circular platforms which pivot about the vertical axis to follow the sun are known. An advantageous solution envisages a floating ring which surrounds the concentrators. The floating ring is present between three rollers arranged around the ring and is thus fixed in place.

The disadvantage of this method is that the three rollers have to be fixed in the earth, which requires three holes in the layer, for example a plastic film, which separates the body of water from the ground. These holes can only rarely be reliably sealed for a relatively long time and often lead to continuous loss of water. Moreover, the location of the platform is permanently fixed by three such rollers.

The invention provides a solution which does not have these disadvantages.

According to the invention, the floating ring is trapped between three rollers. The rollers are rotatably fixed on a base, for example comprising concrete, two rollers advantageously rolling on the inside of the ring while the third roller grips the outside of the ring. It is possible for a roller gripping the outside simultaneously to roll on three platforms resulting in a platform triad. The underside of the base is so smooth and even that a displacement of the total unit comprising rings and base is possible.

To ensure that rings many meters in diameter follow the geometrical circle exactly, the invention provides rollers which grip from the outside and are pressed by suitable guides against the circumference of a ring. One of the rollers adjacent to the inside or outside of the ring is driven and transmits the torque to the floating ring. A roller which grips from the outside and is mounted above the water level, i.e. is surrounded by air, is advantageously used for this purpose.

To enable the three platforms of a triad to be further rotated exactly synchronously through a certain angle, the invention provides, in one embodiment, a chain which is mounted, for example, on the ring and is engaged by a gear ring. Gear wheels may also be replaced by an electronically controlled ring which has optical or magnetic markings instead of teeth.

Instead of control by the movement of the sun, calculated signals are preferably used according to the present invention. In the case of a friction wheel drive, however, the conversion of these signals to the rotation of the platform would fail because transmission of the torque from the friction wheel to the platform would entail slippage. Digital transmission between the gear and the platform should therefore be included, as is possible by gear transmission. If the platform cannot be provided with teeth, the invention envisages a ring of signal generators on the platform. These may be, for example, small reflective plates which reflect the light beam of a sensor. In this method, the rotation speed of the platform is calculated by means of a processor. If said speed exceeds the required value, the speed of the gear motor is somewhat reduced; if said speed is below the required value, the required value is reached by accelerating the motor.

Optical counting of the co-rotating signal generators can also be replaced by a magnetic sensor which registers the magnetic field change of ferromagnetic or permanent magnetic signal generators. Furthermore the reflection of acoustic signals can be used for comparison with required values.

For fixing the concentrator-holding troughs within the floating ring, the invention provides strand-like partitions which carry ball bearings and are arranged between the troughs. The platforms have no mechanical structural element in the center of the platform. However, the power is led out there through two very flexible cables which permit daily rotation of the platforms. A sun locator can also be used for controlling the speed of revolution.

It is advantageous if the driving of the floating ring can be effected in successive pulses. Depending on the time interval of the pulses, the angle of incidence experiences small deviations from the respective required value. The invention compensates these deviations by directing the focus of the concentrator lens not directly onto the photovoltaic cell but onto that area of a glass body which points towards the sun, which glass body mixes the rays by internal reflection and ensures that they strike a photocell connected to the glass body with uniform distribution. This arrangement ensures that, even when the direction of incidence of the cone of rays deviates from the required direction by considerable angular magnitudes of, for example, ±2°, the entire radiation stream reaches the photoelectric cell. The magnitude of the realizable tolerance is determined by the ratio of the magnitude of that area of the glass body which points toward the sun to the diameter of the focal area. This arrangement also compensates errors which arise in the conversion of the pulses into mechanical distances in the gear setup, so that the tolerances are permitted to be far greater than in the case of sun-tracking gears according to the prior art. This leads in each case to a considerable reduction of the production costs of the gears.

Concentrating solar power converters with mechanical tracking of the sun lead to high efficiencies but to date have required tracking devices having the precision of the tracking devices of planetariums.

The invention thus shows how high precision, which gives rise to high costs, can be avoided. To do so, the invention decouples the orientation of the radiation-receiving components from the radiation-converting components in that the concentration of the concentrating apparatus leads to as small a focal region as possible, which is directed toward the glass body whose entry area for the extremely concentrated radiation stream is several times larger, for example twenty times larger, than the area of the focal region, and in that the rays entering the glass body are led to an energy converter, for example a photoelectric cell, which divides the radiation stream into a heat stream and an electron stream. If the required position of the focal region lies on the entry area of the glass body, in the center of this entry area, the invention permits a shift of the focal region in the horizontal direction and at right angles thereto until the focal region reaches the edge of the entry area. That ray of the concentrated radiation cone which is displaceable perpendicular to the sun rays is therefore permitted to deviate from the direction of the sun rays by an angular magnitude which is all the greater the shorter the focal length of the cone of rays in relation to the size of the entry area into the glass body, without energy of the radiation stream being lost thereby for the photoelectric cell. This means that an accuracy guaranteeing loss-free operation is always achieved even in the case of a large tolerance in the mechanical tracking device, i.e. that the total concentrated radiation stream is utilized.

Partitions which run along chords pass through the floating, circular rings. At short intervals from one another, these partitions contain ball bearings which provide a mounting for axle journals which are fixed to troughs and by means of which the troughs are pivotable. Perpendicular to the partitions are steel cables which are tensioned so that the circular shape of the floating ring is ensured.

The troughs are formed in such a way that the region projecting into the body of water produces an exactly vertical lifting force at each angular position so that there is no torque. The troughs themselves are conical, with the result that they are stackable, which considerably reduces the transport costs between the production location and the erection location. A buoyancy aid in the form of a cylinder having a circular cross-section is fixed to that side of each trough which faces the body of water, said buoyancy aid preventing buoyancy-related torques. The troughs are covered with lenses of transparent plastic. Within a circumscribed circle, the lenses are dished, and the cross-section through the lens runs there along a spherical surface whose sphere axis passes through the point of intersection of the diagonals of the circumscribed square. The circular region carries refractive grooves. The four edge regions have fluting which produces an internal reflection for deflecting the radiation.

Those edges of the lenses which run in the longitudinal direction of the troughs are bent by a small amount, with the result that they can be connected to the walls of the troughs so as to be displaceable by a small amount so that they perform the function of structural elements.

The troughs each consist of an open tray which has conical walls, making stacking possible. The trough floats in the water layer and is pivotable about its horizontal axis. In order to avoid the generation of a torque, a buoyancy aid which continues the round shape of the bottom region is fixed to the wall pointing toward the sun. As a result of this, the trough is supported by buoyancy, and a torque about the axis is avoided. The weight of the lens is compensated by a balancing weight arranged in the lower region of the trough.

The control of the azimuthal speed and the function of the elevation gear can be performed by means of recorded astronomical data. However, the invention provides a sun tracking unit so that azimuth and elevation control is effected as a function of the movement of the sun. However, it has been found that, when the sun rays are blocked, for example by a cloud, there is the danger that the focus migrates to the new position when the blocking comes to an end and in this way can cause damage, for example by burning of the cable insulation. The invention prevents this by an auxiliary drive which continues the azimuth-following migration, i.e. the rotation of the platform, when the sun-track migration ceases. Here, the cessation of the gear motor supply, for example by a cloud, is taken as a signal for switching on the auxiliary drive.

For preventing evaporation of the water layer, the invention provides a thin layer of a high-boiling liquid which is lighter than water and also prevents the formation of mosquito larvae. In regions where frost is to be expected, the invention envisages that an alcohol, e.g. glycol, is mixed with the body of water. Another solution for preventing evaporation, but also for protecting from night frosts, comprises arranging, between successive troughs, of flexible film which covers the water surface. In regions where there is a danger of frost, a heat-insulating film is provided.

The invention is to be described with reference to the figures:

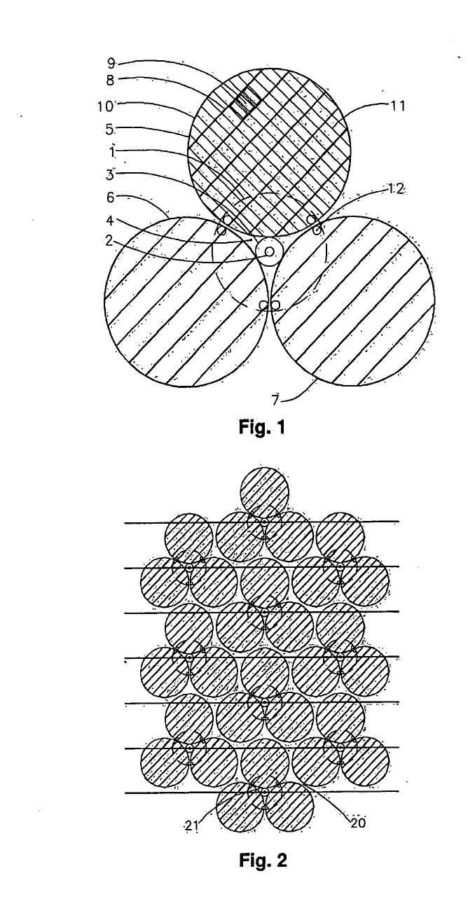

FIG. 1 shows the basic setup of a triad

FIG. 2 shows the nesting together of triads

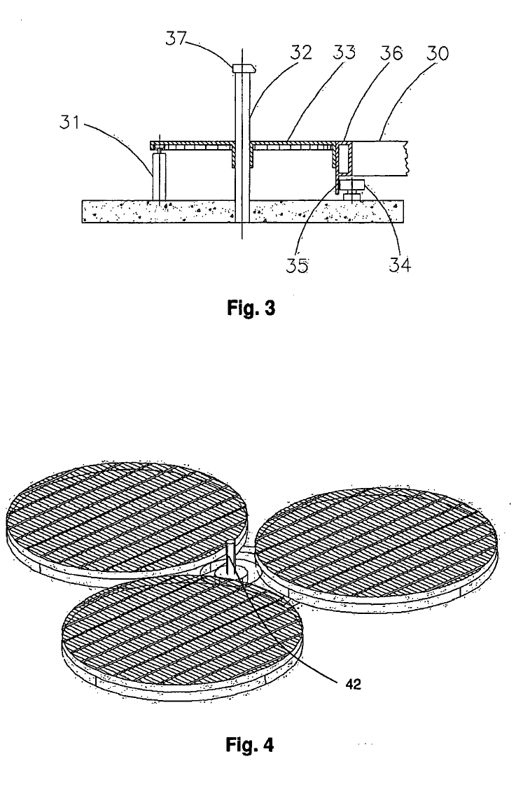

FIG. 3 schematically shows a vertical section through the interstitial region

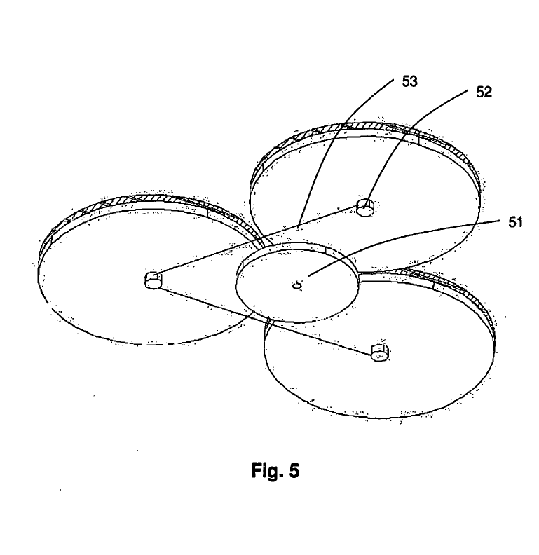

FIG. 4 shows the plan view of a triad

FIG. 5 shows a triad viewed from below

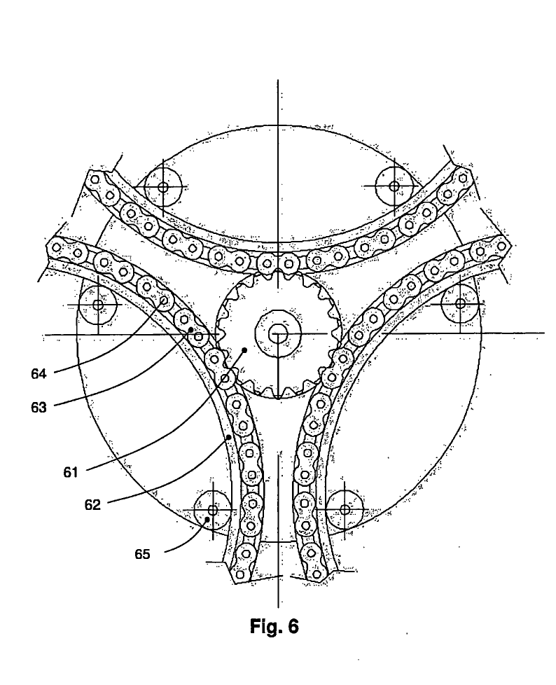

FIG. 6 shows a drive having a central wheel and roller chains

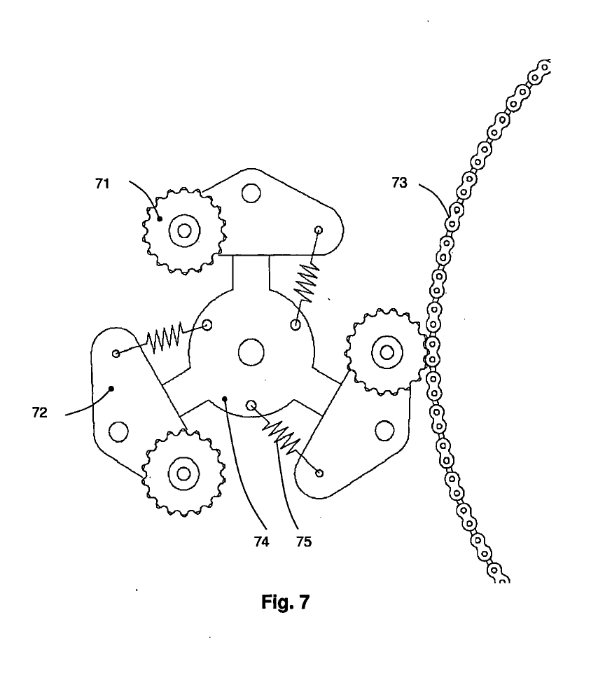

FIG. 7 shows a transmission arrangement having sprocket wheels

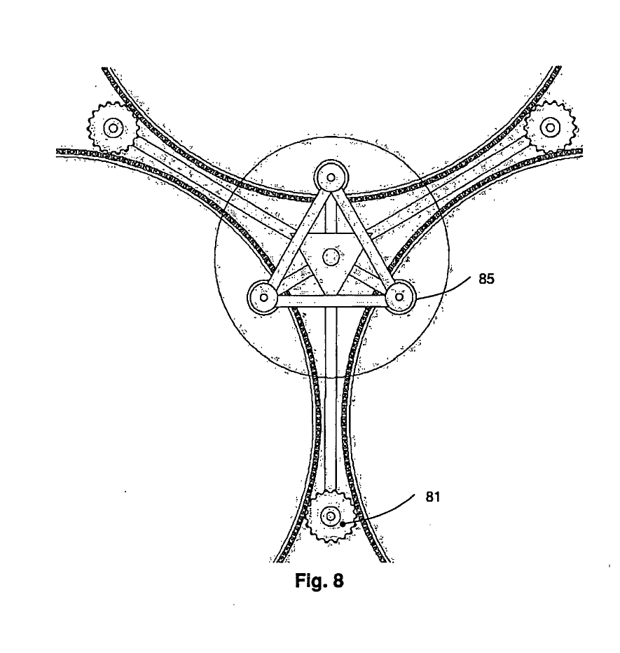

FIG. 8 shows an arrangement of the driving and guiding rollers

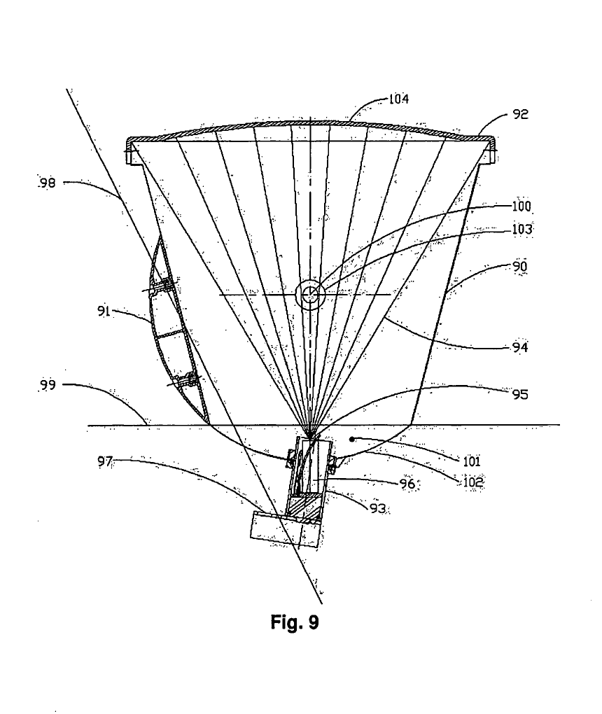

FIG. 9 shows the trough and the lenses with buoyancy aid

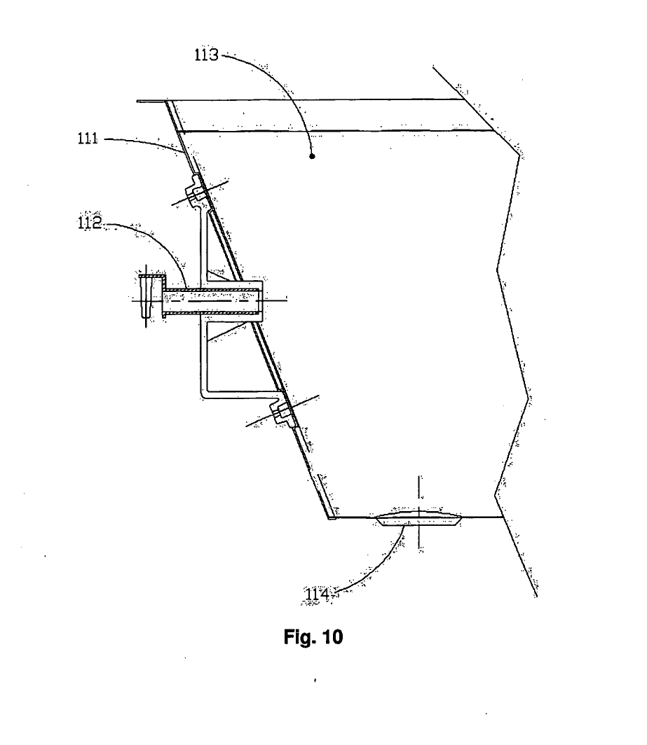

FIG. 10 shows the end wall of a trough

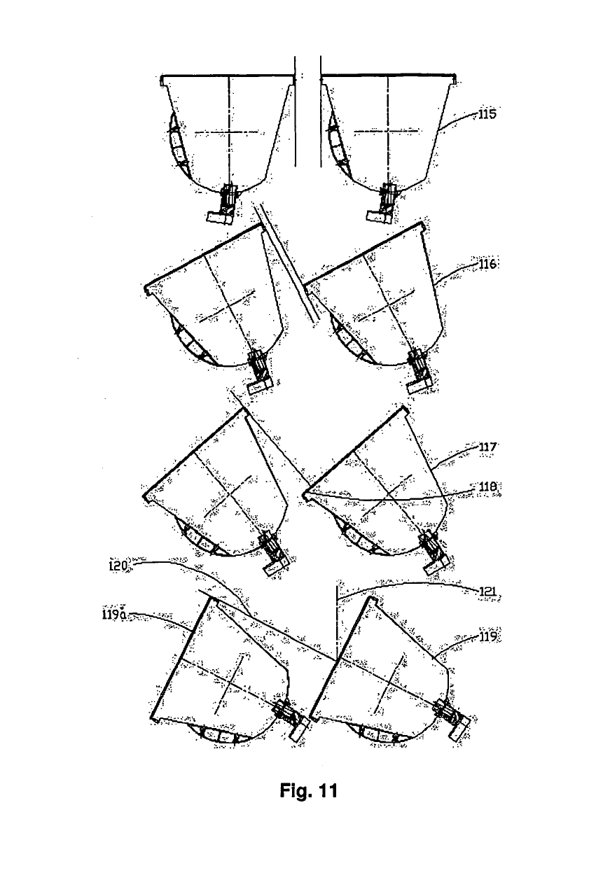

FIG. 11 shows the irradiation at different elevation

FIG. 12 shows the stacking of troughs

FIG. 13 shows the partition and the coupling elements

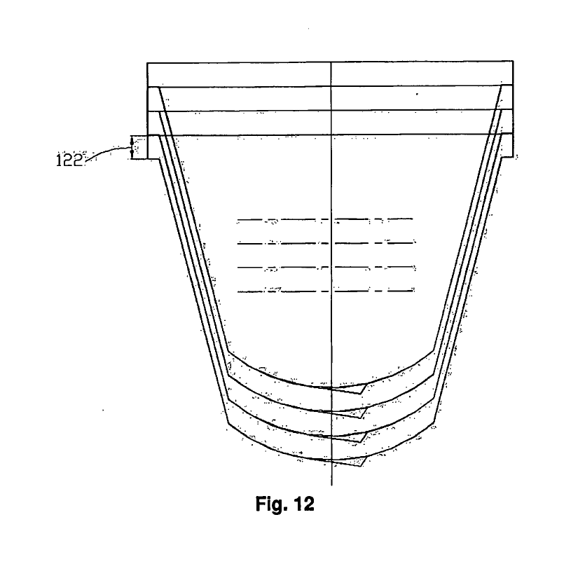

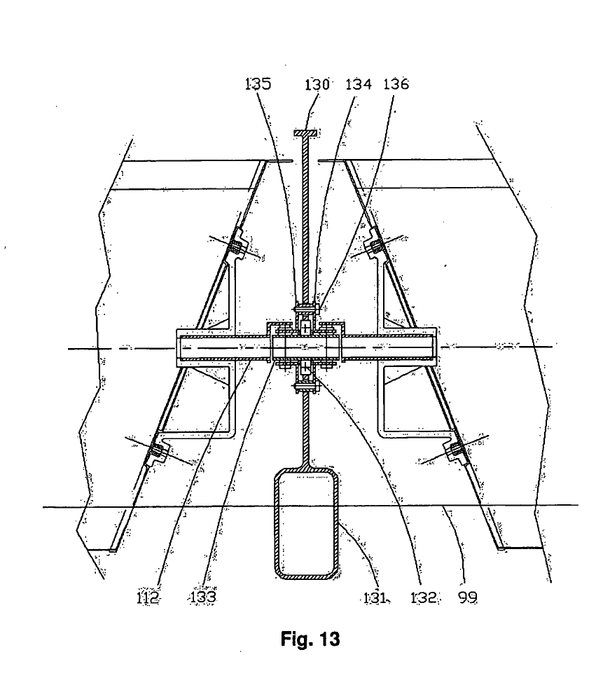

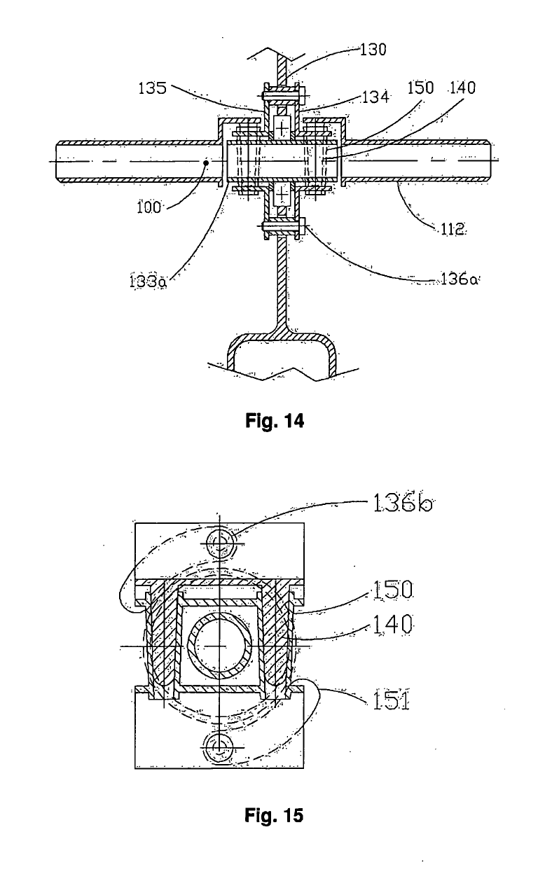

FIG. 14 shows the coupling elements and the ball bearing

FIG. 15 shows the holes through the partition

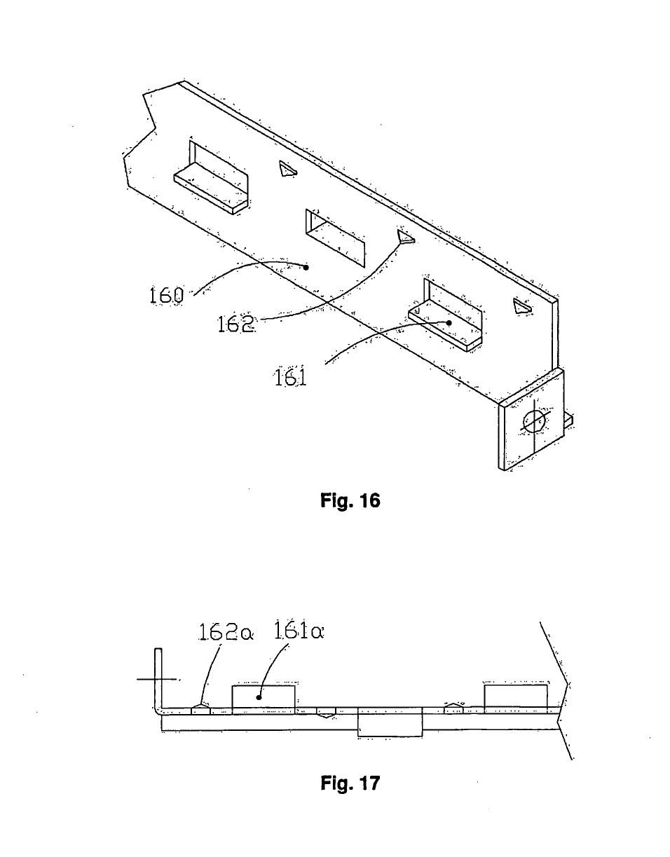

FIG. 16 shows the web below adjacent lenses

FIG. 17 shows the web and the projections

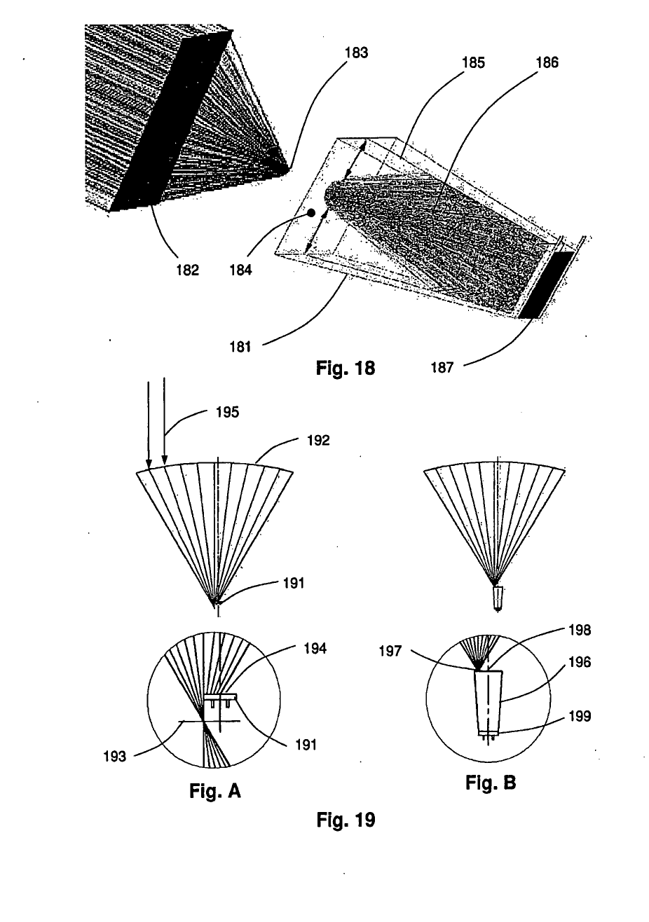

FIG. 18 shows the secondary optical system

FIG. 19 shows the comparison with the prior art

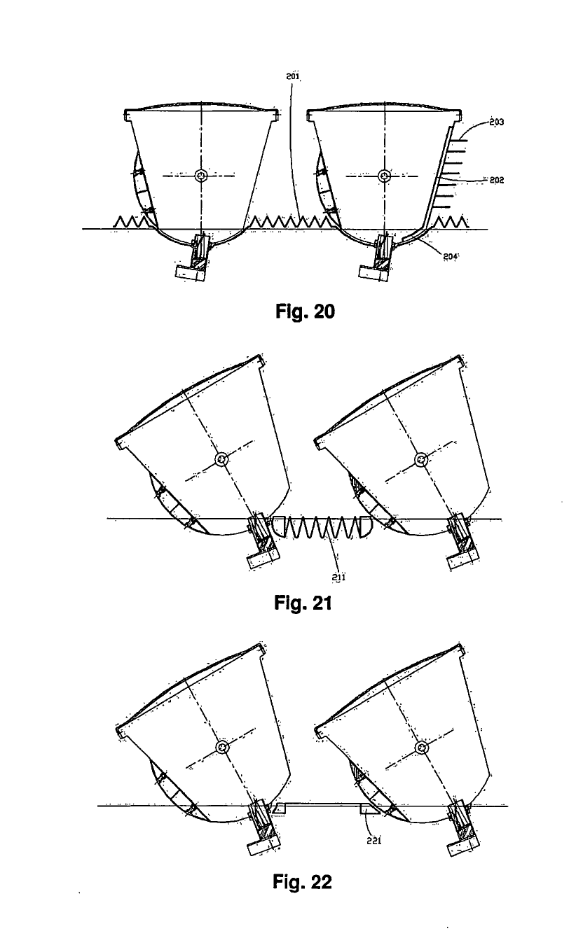

FIG. 20 shows the covering of the body of water with heat removal

FIG. 21 shows the folded covering

FIG. 22 shows a floating cover body

FIG. 1 shows the basic setup of a triad. Present in the center of the concrete base 1 is the column 2 on which two rollers 12 are arranged for each floating ring. The drive wheel 3 which drives the three platforms 5, 6 and 7 is at the midpoint of the interstitial region 4. Between the partitions 8, troughs 9 are arranged so as to be pivotable about the horizontal axis. Metal wires 11 by means of which the circular shape of the floating ring 10 is ensured run between the troughs 9. The platforms are surrounded by floating rings 10. In the evening, the lenses are cleaned. For this purpose, a spray nozzle is arranged on the central column 2, through which spray nozzle a pump arranged in the base outputs filtered water. During this procedure, the platform rotates through 180°.

FIG. 2 shows a larger base area comprising triads. The distance 20 between the troughs is such that a person can access everywhere. An interstitial region 21 remains between the three rings.

FIG. 3 schematically shows a vertical section through the interstitial region. One of the three platforms 30 is shown in section. At the midpoint of the interstice is the column 32 on which the driving wheel 33 is mounted. Driving is effected via the underwater gear motor 31. The circumference of the driving wheel 33 and the circumference of the platform 30 are toothed. Two of the rollers 34 touch the floating ring 36 at the internal diameter 35 so that the floating ring 36 is fixed a distance away from the column 32 and at the circumference. A pivotable spray nozzle 37 which cleans the lenses with filtered water in the evening is arranged at the upper end of the column 32.

FIG. 4 shows the plan view of a triad having a column 42.

FIG. 5 shows the same triad from the underside, where the concrete base 51 is located, the underside of which is even and smooth. The total unit can thus be moved to the desired position on the film which separates the body of water from the bottom, the platforms being supported by the water. Two highly flexible cables 52 through which the power is fed into the connecting cable 53 emerge in each case at the center of the platform.

FIG. 6 shows the transmission of the torque via a central gear wheel 61. A roller chain 63 is fixed on each of the floating rings 62 in such a way that extended chain pins 64 project into holes in the floating rings 62. Stationary rollers 65 fixed on the concrete base engage the inside of the floating rings 62.

FIG. 7 shows a torque-transmitting construction having three sprocket wheels 71. Each of these wheels 71 is mounted on a rocker 72. The three rockers are pivotably fixed to a central disk 74 and are pressed against the chain 73 by tension springs 75.

FIG. 8 shows a construction in which the distance of the three platforms from one another is determined by rollers 81. Instead of the rollers lying in the water layer, here the rollers 85 prevent the three floating rings from moving apart. The advantage of this solution is that all mechanical elements are above the water layer. Driving is effected via a gear motor which drives one of the three sprocket wheels 81 which determine the distance between the 3 platforms.

FIG. 9 shows the cross-section through a trough comprising the tray 90, the buoyancy body 91, the lens 92 and the energy converter 93. The pencil of rays 94 produces the focal point 95 on the entry area of the secondary optical system 96. The housing of the energy converter 93 makes an acute angle with the axis of the secondary optical system. Even in an extreme skew position relative to the water surface 98, the energy converter 93, in cooperation with the foot 97 reaches the body of water in order to pass the relatively small waste heat stream resulting at the extreme angle of 26 degrees into the body of water. The trough is pivotable about the horizontal axis 100. The level line 99 characterizes the water surface at 90 degrees elevation. The region 101 immersed in the water, together with the buoyancy body 91, results in constant buoyancy which corresponds to the weight of the trough. Owing to the cylindrical regions 91 and 102, the distance between the water surface and the axis 100 does not change, so that the axle journal 103 experiences neither a shift in height nor a hydraulically caused torque. The lens 92 is square and has an inscribed circular area which runs along a spherical section 104.

FIG. 10 shows the end region of a trough which holds up to 10 lenses and the energy converter. The end wall 111 runs obliquely to the walls of the trough tray so that they can be stacked without buoyancy aid 91a. The hollow axle journal 112 through which the electric cables lead is arranged on the end plate 111. The bottom of the sheet metal wall 113 has a stamped out area 114 into which the energy converter 93 is screwed.

FIG. 11 shows the pivot position of a trough 115 at 90 degree altitude of the sun. The trough 116 shows pivoting about 28 degrees. The trough 117 is overshadowed by the adjacent trough by a vanishingly small percentage of the entry area 118. The trough 119 shows the entry situation in the morning at the limiting angle of 63 degrees between the incident radiation 120 and the vertical 121, where 46% of the lens is in the shadow of the adjacent trough 119a. However, the trough occupies this skew position only for a few minutes. By means of a secondary optical system, the radiation stream entering is spread uniformly over the area of the photoelectric cell.

FIG. 12 shows a cross-section from which it is evident that the trough body can be stacked for transport, the distance 122 being kept as small as possible.

FIG. 13 shows the partition 130 whose lower region 131 is hollow and projects into the water line 99 to such an extent that the partition is supported by buoyancy. Arranged over the length of the partition are holes through which a hollow axle 113 which is flush with the axle journals 112 passes and which is mounted in a plastic ball bearing 132. On the two sides of the partition 130, holders 134 and 135 are connected to one another by screws 136 which pass through the holes in the partition.

FIGS. 14 and 15 show the region of the hole in the wall 130 on a larger scale. The holder elements 134 and 135 have, as is evident from drawing 15, conical sleeves 150 into which project conical pins 140 which are fixed to the axle journals 112. Slots 151 through which the screws 136b project are arranged in the partition 130 so that a torque about the hollow axle 133a is transmitted. This arrangement permits a trough to be lifted out of an assembly perpendicularly to the axis of rotation.

FIG. 16 shows a web 160. Four to five lenses form a lens unit. Arranged between two lens units is the web 160 which, as is evident from FIG. 17, has tabs 161, 161a on which the free end of the lens units rests.

FIG. 17 shows the sheet metal tips 162 and 162a (shown in FIG. 16) by means of which rubber piping which prevents the penetration of rain water into the trough is held in place.

FIG. 18 shows the secondary optical system 181 which is separated from the concentrator lens 182 by a distance which corresponds exactly to the focal length. For representational reasons a space is left between the focal point 183 and that area 184 of the secondary optical system 181 which faces it and is shown from the inside. The concentrator lens 182 concentrates the sunlight to about 8000 suns, and the focal region 183 is only a few millimeters in size. The lateral walls 185 of the secondary optical system reflect the radiation stream 186, which at the end is incident on the photoelectric cell 187 which is optically connected to the secondary optical system. If the sun rays are not incident exactly perpendicularly on the concentrator lens 182, the focal point 183 migrates to the entry area 184 which is much larger in terms of area—compared with the focal region—so that angular deviations within a tolerance interval of, for example, ±2 degrees do not lead to a reduction in power, whereas all known systems comprising two-axis sun tracking permit only an interval of <0.1 degree. The large tolerance interval permits a mechanical setup without expensive precision parts.

FIG. 19 shows the comparison of a concentrator B according to the invention and a concentrator according to the prior art A. In FIG. 19A the photoelectric cell 191 is above the focal plane 193. An angular deviation between the sun rays 195 and the lens 192 results in rays passing by the photoelectric cell 191 and simultaneously in the photoelectric cell remaining unexposed over a region 194, which leads to thermal stresses. FIG. 19B shows the secondary optical system 196 according to the invention and the focal region 197, which has migrated by a considerable amount from the central ray 198. The total radiation energy enters the secondary optical system 196 and, as shown in FIG. 18, reaches the photoelectric cell 199.

FIG. 20 shows a flexible film 201 which extends over the total length of the diameter of the floating ring. Heat pipes 202 which transfer the heat via ribs 203 to the outside air serve for removing heat from the water. The heat pipe conducts heat only from the lower region 204 to the ribs 203; the opposite direction leads to no heat transfer since the filling of the heat pipe freezes so that negative temperatures are not passed into the water.

FIG. 21 shows an arrangement in which the film 211 is folded to an extreme extent to increase the size of the water surface in order to increase the heat transfer between the water and the outside air.

FIG. 22 shows the floating element 221 which seals the space between two troughs.

### LIST OF REFERENCE NUMERALS

1, 51 Concrete base
2, 32, 42 Column
12, 34, 65, 85 Roller
3, 33 Drive wheel
5, 6, 7, 30 Platform
4, 21 Interstitial region
8, 130, 131, 151 Partition
9, 90, 115, 116, 117, 119, 119a Trough
11 Metal wire
10, 36, 62 Ring
20, 122 Distance
31 Gear motor
35 Internal diameter of ring
37 Spray nozzle
52 Highly flexible cable
53 Connecting cable
61 Central gear wheel
63, 73 Roller chain
64 Chain pin
71, 81 Sprocket wheels
72 Rocker
74 Central disk
75 Tension spring
91, 91a Buoyancy body
92, 182, 192 Lens
93 Energy converter
94 Pencil of rays
95, 183 Focal point
96, 181, 184, 185, 196 Secondary optical system
97 Foot
98 Water surface
100 Horizontal axis
99 Water line
101 Immersed region
91, 102 Cylindrical region
103, 112 Axle journal
104 Spherical section
111 End wall
113 Sheet metal wall
114 Stamped out area
118, 184 Entry area
120 Incident radiation
121 Vertical
133, 133a Hollow axle
132 Ball bearing
134, 135 Holder
136, 136b Screw
150 Sleeve
140 Conical pin
160 Web
161, 161a Tab
162, 162a Sheet metal tip
183, 197 Focal region
186 Radiation stream
187, 191, 199 Photoelectric cell
193 Focal plane
195 Sun rays
194 Unexposed region
198 Central ray
201, 211 Film
202, 204 Heat pipe
203 Ribs
Floating element

1. A system for producing solar power, consisting of a rotating, circular platform which produces solar power and rotates about a vertical axis, the platform (5, 6, 7) containing a plurality of floating troughs (9, 90, 91) having photoelectric cells (187, 199), which are covered by concentrating lenses (92, 182, 192), wherein the platform (5, 6, 7) is surrounded by a circular, floating ring (10, 36) which is held in place by an apparatus gripping only one region of its circumference.

2. The system as claimed in claim 1, wherein said apparatus contains two or more rollers (12, 34, 65, 85) which clasp the ring (10, 36).

3. The system as claimed in claim 2, wherein a rotation of the ring (10, 36) is effected by virtue of the fact that one of the rollers (33, 61, 71, 81) is driven by a motor (31) and that this roller (33, 61, 71, 81) transmits the torque to the ring (10, 36).

4. The system as claimed in claim 3, wherein the transmission of the torque is effected via the toothed ring (61, 71) which drives a roller chain (63, 73) which is fixed to the floating ring (10, 36, 62).

5. The system as claimed in claim 4, wherein the toothed ring (61, 71, 81) is pressed under spring load against the roller chain (63, 73).

6. The system as claimed in claim 1, wherein each trough consists of two bodies, the first of which is in the form of an elongated rectangular trough tray (90) having conically diverging walls, whose bottom forms a cylindrical section (102) whose geometric axis (100) is in the vicinity of the axis of gravity of the trough, and the second body (91) of which is in the form of a cylinder having a circular cross-section, whose cylindrical wall has the same radius as the bottom of the first body, the second body being fixed to that wall of the first body which points toward the sun so that the curve of the bottom of the first body continuously follows the curve of the second body.

7. The system as claimed in claim 6, wherein the walls (111) of the trough diverge toward the top so that stacking of the trough bodies is possible.

8. The system as claimed in claim 6, wherein the cylindrical region (102) of the outer area, which consists of the bottom of the first body and the curved wall of the second body (91), is immersed in the body of water (98, 99) to such an extent that the trough is supported by buoyancy.

9. The system as claimed in claim 8, wherein weights for weighting are arranged in the trough so that the perpendicular vector of the lifting force intersects the axis of gravity of the trough, with the result that the generation of a torque about the pivot axis of the trough is prevented.

10. The system as claimed in claim 1, wherein vertically oriented, strip-like partitions (130, 131) run within the floating ring (10, 36), parallel to an imaginary diameter, which partitions contain ball bearings (132) through which in each case a hollow shaft (133) runs, which hollow shafts are connected via coupling elements (135, 136) to axle journals (112) of the adjacent troughs.

11. The system as claimed in claim 10, wherein the partitions (130, 131) in the lower region displace so much water that the partitions are supported by buoyancy.

12. The system as claimed in claim 10 wherein the coupling elements (135, 136) permit a trough to be separated by pulling out the trough in a plane perpendicular to the pivot axis.

13. The system as claimed in claim 10, wherein one side of the coupling has conical pins (140) in a plane at right angles to the pivot axis, and wherein the other side of the coupling has sleeves (150) into which those pins (140) can be pushed.

14. The system as claimed in claim 3, wherein three floating rings (10, 36) are combined to form a triad and enclose an interstitial space (4, 21) between them.

15. The system as claimed in claim 14, wherein the three rings (10, 36) touch a central drive wheel (33, 61) via which the three rings (10, 36) are synchronously rotated.

16. The system as claimed in claim 2, wherein two rollers (34) which are located under the water surface and prevent outward migration grip the inner surface of the ring (10, 36).

17. The system as claimed in claim 14, wherein a base plate (1, 51) which is connected via a drive device (31) to the rings (10, 36) is arranged below the interstitial space (4, 21).

18. The system as claimed in claim 2, wherein in each case a roller (34) connected above the water level (99) to the base plate (1, 51) rolls on the inner surface of the ring (10, 36).

19. The system as claimed in claim 18, wherein, between adjacent rings (10, 36) of a triad, rollers (33, 61, 71, 81) roll on the outer surface of the rings (10, 36).

20. The system as claimed in claim 19, wherein these rollers (71, 81) are mounted in a star-like holding device (74).

21. The system as claimed in claim 1 wherein the troughs are connected to one another via hollow axles (133) through which electric cables lead.

22. The system as claimed in claim 10, wherein cables (11) which run along chords are stretched at right angles to the partitions (130, 131).

23. The system as claimed in claim 1, which comprises a concentrator device having a concentrator lens and a photovoltaic cell, a very small focal region (183, 197) being formed by concentration of the entering rays to more than 1000 suns, which focal region is incident on the entry side of a preferably square glass body (181) which is optically connected to the photovoltaic cell (187), the entry side (184) of the glass body (191) being more than 10 times larger than the cross-section of the focal area.

24. The system as claimed in claim 23, wherein the glass body (181) has polished walls (185) at which the entering rays (186) experience an internal reflection.

25. The system as claimed in claim 24, wherein the photovoltaic cell (187) is separated from the cooling body by a layer whose thermal expansion is close to that of the photovoltaic cell.

26. The system as claimed in claim 25, wherein a body which has good thermal conductivity and whose area parallel to the photovoltaic cell (187) is at least twice as large as the photovoltaic cell is located under this layer.

27. The system as claimed in claim 26, wherein an electrically insulating layer conducting the heat flow is present under this body.

28. The system as claimed in claim 1, which comprises a device for preventing water evaporation, for example via a film running under the troughs.

29. The system as claimed in claim 28, wherein a floating strip (130, 131) is arranged between the troughs (9).

30. The system as claimed in claim 28, which comprises heat pipes (202, 204) which perform heat transport from the water to the outside air.

31. The system as claimed in claim 30, wherein the heat pipes (202, 204) contain a heat-transfer medium which freezes at about 0 degrees Celsius.

32. A floating trough as part of a photovoltaic installation, in particular as part of a system for producing electric power from solar energy, as claimed in claim 1, which comprises two bodies, the first of which is in the form of an elongated rectangular trough tray (90), having conically diverging walls, whose bottom forms a cylindrical section (102), whose geometric axis (100) is in the vicinity of the axis of gravity of the trough, and the second body (91) of which is in the form of a cylinder having a circular cross-section, whose cylindrical wall has the same radius as the bottom of the first body, the second body being fixed to that wall of the first body which points toward the sun in such a way that the curve of the bottom of the first body always follows the curve of the second body.

33. The system as claimed in claim 32, wherein the walls (111) of the trough diverge toward the top so that stacking of the trough bodies is possible.

34. The system as claimed in claim 32, wherein the cylindrical region (102) of the outer area, which consists of the bottom of the first body and the curved wall of the second body (91), is immersed in a body of water (98, 99) to such an extent that the trough is supported by buoyancy.

35. The system as claimed in claim 34, wherein weights for weighting are arranged in the trough so that the perpendicular vector of the lifting force intersects the axis of gravity of the trough, with the result that the generation of a torque about the pivot axis of the trough is prevented.

36. A concentrator device, in particular for concentrating sun rays, comprising a concentrator lens and a photovoltaic cell, wherein concentration of the rays to more than 1000 suns results in the formation of a very small focal region (183, 197) which is incident on the entry side of a preferably square glass body (181) which is optically connected to the photovoltaic cell (187), the entry side (184) of the glass body (181) being more than 10 times larger than the cross section of the focal area.

37. The system as claimed in claim 36, wherein the glass body (181) has polished walls (185) at which the entering rays (186) experience an internal reflection.

38. The system as claimed in claim 37, wherein the photovoltaic cell (187) is separated from a cooling body by a layer whose thermal expansion is close to that of the photovoltaic cell.

39. The system as claimed in claim 38 wherein a body which has good thermal conductivity and whose area parallel to the photovoltaic cell (187) is at least twice as large as the photovoltaic cell is present under this layer.

40. The system as claimed in claim 39, wherein an electrically insulating layer conducting the heat flow is present under this body.
